(19) United States
(12) Patent Application Publication
(10) Pub. No.: US 2024/0371646 A1
(43) Pub. Date: Nov. 7, 2024

(54) PROCESS CONTROL METHOD FOR PATTERN WAFER INDEX POLISHING

(71) Applicant: Applied Materials, Inc., Santa Clara, CA (US)

(72) Inventors: Jimin ZHANG, San Jose, CA (US); Harry Q. LEE, Los Altos, CA (US); Jianshe TANG, San Jose, CA (US); Brian J. BROWN, Palo Alto, CA (US)

(21) Appl. No.: 18/611,430

(22) Filed: Mar. 20, 2024

Related U.S. Application Data
(60) Provisional application No. 63/463,159, filed on May 1, 2023.

(51) Int. Cl. H01L 21/304; B24B 37/013; B24B 37/04; B24B 49/10; H01L 21/66

(52) U.S. Cl. CPC H01L 21/304; B24B 37/013; B24B 37/042; B24B 49/105; H01L 22/26

(57) ABSTRACT

In one embodiment, a method of processing a substrate in a chemical mechanical polishing (CMP) system, comprises determining an orientation of a substrate relative to a first carrier head. The method further includes initiating a polishing process of a surface of the substrate engaged with a polishing pad. The method further includes scanning, during the polishing process, a first portion of the surface of the substrate repeatedly using at least one endpoint sensor coupled to the polishing pad to generate orientation dependent scan data of a property of the first portion of the surface. The method further includes comparing the orientation dependent scan data to a library of orientation dependent scan data to determine when the endpoint of the polishing process has been reached.

### CROSS-REFERENCE TO RELATED APPLICATIONS

This application claims priority to and the benefit of U.S. Provisional Application No. 63/463,159 entitled “Process Control Method for Pattern Wafer Index Polishing” filed on May 1, 2023. The aforementioned application is incorporated by reference herein.

### BACKGROUND

### Field

The present disclosure relates to chemical mechanical polishing (CMP), and more specifically to analyzing an endpoint of a CMP process.

### Description of the Related Art

An integrated circuit is typically formed on a substrate by sequential deposition of conductive, semiconductive, and/or insulative layers on a semiconductor substrate. A variety of fabrication processes require planarization of a layer on the substrate. For example, one fabrication process involves depositing a filler layer over a non-planar surface and planarizing the filler layer. For certain applications, the filler layer is planarized until a top surface of a patterned layer is exposed. For example, a metal layer can be deposited on a patterned insulative layer to fill trenches and holes in the insulative layer. After planarization, the remaining portions of the metal in the trenches and holes of the patterned layer form vias, plugs, and lines to provide conductive paths between integrated circuits (ICs) on the substrate. As another example, a dielectric layer can be deposited over a patterned conductive layer, and then planarized to enable subsequent photolithographic processes.

Chemical mechanical polishing (CMP) is one accepted method of planarization. This planarization method typically requires that the substrate be mounted on a carrier head. The exposed surface of the substrate, the surface with the layer deposition, is typically placed against a rotating polishing pad. The carrier head provides a controllable load on the substrate to urge it against the polishing pad. A polishing slurry with abrasive particles is typically supplied to the surface of the polishing pad and spreads in between the substrate and the polishing pad. The polishing pad and the carrier head each rotate at a constant rotational speed and the abrasive slurry removes material from one or more of the layers.

Conventional CMP operations utilize a sensor disposed in a polishing platen to detect the endpoint of a CMP process. However, the data collected from the sensor in conventional designs varies over time due to the differing portions of the substrate that traverses the sensor during the polishing process. Due to variations in the material thickness and differing material types commonly found on patterned semiconductor substrates, it is hard to reliably detect the endpoint of a conventional CMP process. For example, one factor that affects a CMP system's ability to reliably and repeatably detect an endpoint of a conventional CMP process relates to the inability of conventional CMP processes to know whether a change in a sensed property of the film that is being polished is related to the material that has been removed or is an artifact of the structure of the patterned semiconductor substrate. Therefore, there is a need in the art for an improved endpoint detection process.

### SUMMARY

In one embodiment, a method of processing a substrate in a chemical mechanical polishing (CMP) system, comprising performing a polishing process on a plurality of substrates, wherein each polishing process performed on each substrate comprises: transferring each of the substrates of the plurality of substrates to a surface of a first polishing pad, wherein transferring each of the substrates comprises: retrieving, by use of a carrier head that is oriented in first orientation, the substrate that is positioned in a second orientation on a substrate receiving surface within the CMP system; polishing a surface of each of the substrates on the first polishing pad coupled to a first platen, wherein the first platen comprises one or more sensors that are configured to detect a property of a material disposed on the surface of each of the substrates, one of the one or more sensors is positioned in a third orientation, and a controller that is configured to, at a beginning of the process of polishing the surface of each of the substrate, cause the substrate, the carrier head and the one or more sensors on the platen to be positioned in substantially the same orientations relative to each other; scanning, by the one or more sensors, the surface of each of the substrates during the process of polishing the surface of each of the substrates, wherein scanning the surface of each of the substrates comprises generating scan data that comprises a detected property of the material disposed on the surface of each of the substrates; determining that the generated scan data substantially matches library scan data that is stored in memory of the controller; determining a difference exists between an attribute of a portion of the generated scan data with an attribute of a portion of the library scan data; and adjusting a characteristic of the process of polishing the surface of each of the substrates based on the determined difference between the attribute of the portion of the generated scan data and the attribute of the portion of the library scan data.

In one embodiment, a method of processing a substrate in a chemical mechanical polishing (CMP) system, comprising performing a polishing process on a plurality of substrates, wherein each polishing process performed on each substrate comprises transferring each of the substrates of the plurality of substrates to a surface of a first polishing pad. Wherein transferring each of the substrates comprises retrieving, by use of a carrier head that is oriented in first orientation, a substrate that is positioned in a second orientation on a substrate receiving surface within the CMP system. The method further comprises polishing a surface of each of the substrates on the first polishing pad coupled to a first platen. The first platen comprises one or more first sensors that are configured to detect a property of a material disposed on the surface of each of the substrates. The one of the one or more first sensors is positioned in a third orientation. A controller that is configured to, at a beginning of the process of polishing the surface of each of the substrate, cause the substrate, the carrier head and the one or more first sensors on the first platen to be positioned in substantially the same orientations relative to each other. The method further comprises scanning, by the one or more first sensors, the surface of each of the substrates during the process of polishing the surface of each of the substrates on the first polishing pad, wherein scanning the surface of each of the substrates comprises generating first scan data that comprises a first detected property of the material disposed on the surface of each of the substrates. The method further comprises determining a difference exists between an attribute of a portion of the generated first scan data with an attribute of a portion of a first library scan data stored in the controller during the process of polishing the surface of each of the substrates on the first polishing pad. The method further comprises adjusting a characteristic of the process of polishing the surface of each of the substrates on the first polishing pad based on the determined difference between the attribute of the portion of the generated first scan data and the attribute of the portion of the first library scan data.

In one embodiment, a method of processing a substrate in a chemical mechanical polishing (CMP) system comprises transferring a substrate from a first polishing pad to a second polishing pad using a first carrier head. The method further comprises determining, after transferring the substrate to the second polishing pad, an orientation of the substrate relative to the first carrier head. The method further comprises initiating a polishing process of a surface of the substrate on the second polishing pad. The method further comprises scanning, during the polishing process, a first portion of the surface of the substrate a first time using an endpoint sensor coupled to the second polishing pad to generate first orientation dependent scan data of a property of the first portion of the surface. The method further comprises comparing the first orientation dependent scan data to a first library of orientation dependent scan data. The method further comprises scanning, during the polishing process, the first portion of the surface of the substrate a second time using the endpoint sensor to generate second orientation dependent scan data of the property the first portion of the surface. The method further comprises comparing the second orientation dependent scan data to the first library and determining that the endpoint of the polishing process has been reached. The method further comprises stopping the polishing process upon determining that the endpoint has been reached.

In one embodiment, a method of processing a substrate in a chemical mechanical polishing (CMP) system comprises determining an orientation of a substrate relative to a first carrier head. The method further comprises initiating a first polishing process of a surface of the substrate engaged with a first polishing pad, the first polishing process comprising rotating the first polishing pad and rotating the substrate relative to the first polishing pad using the first carrier head. The method further comprises scanning, during the first polishing process, a first portion of the surface of the substrate a first time using a first endpoint sensor coupled to the first polishing pad to generate first orientation dependent scan data of a property of the first portion of the surface. The method further comprises comparing the first orientation dependent scan data to a first library of orientation dependent scan data. The method further comprises scanning, during the first polishing process, the first portion of the surface of the substrate a second time using the first endpoint sensor to generate second orientation dependent scan data of the property of the first portion of the surface. The method further comprises comparing the second orientation dependent scan data to the first library and determining that an endpoint of the first polishing process has been reached. The method further comprises stopping the first polishing process upon determining that the endpoint of the first polishing process has been reached.

In one embodiment, a non-transitory computer-readable medium comprising instructions stored thereon that when executed by one or more processors cause a controller to perform a method of processing a substrate in a chemical mechanical polishing (CMP) system, the method comprising determining an orientation of a substrate relative to a first carrier head. The method further comprises initiating a first polishing process of a surface of the substrate engaged with a first polishing pad, the first polishing process comprising rotating the first polishing pad and rotating the substrate relative to the first polishing pad using the first carrier head. The method further comprises scanning, during the first polishing process, a first portion of the surface of the substrate a first time using a first endpoint sensor coupled to the first polishing pad to generate first orientation dependent scan data of a property of the first portion of the surface. The method further comprises comparing the first orientation dependent scan data to a first library of orientation dependent scan data. The method further comprises scanning, during the first polishing process, the first portion of the surface of the substrate a second time using the first endpoint sensor to generate second orientation dependent scan data of the property of the first portion of the surface. The method further comprises comparing the second orientation dependent scan data to the first library and determining that an endpoint of the first polishing process has been reached. The method further comprises stopping the first polishing process upon determining that the endpoint of the first polishing process has been reached.

In one embodiment, a method of processing a substrate in a chemical mechanical polishing (CMP) system, comprises determining an orientation of a substrate relative to a first carrier head. The method further includes initiating a polishing process of a surface of the substrate engaged with a polishing pad. The method further includes scanning, during the polishing process, a first portion of the surface of the substrate repeatedly using at least one endpoint sensor coupled to the polishing pad to generate orientation dependent scan data of a property of the first portion of the surface. The method further includes comparing the orientation dependent scan data to a library of orientation dependent scan data to determine when the endpoint of the polishing process has been reached.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 depicts a schematic top view of an exemplary chemical mechanical polishing (CMP) system.

FIG. 2A depicts a schematic sectional view of an exemplary polishing station of the CMP system from FIG. 1 according to embodiments described herein.

FIG. 2B is a top view of a front surface of a substrate polished on the polishing station of FIG. 2A according to embodiments described herein.

FIG. 3 depicts a schematic top view of the carrier head positioned at a scan position on the polishing pad from the polishing station of FIG. 2A according to embodiments described herein.

FIG. 4 depicts a top view of a front surface of a substrate scanned by an orientation sensor of the polishing station of FIG. 2A according to embodiments described herein.

FIG. 5 depicts a top view of a front surface of a substrate showing the scan paths of endpoint sensors of the polishing station of FIG. 2A according to embodiments described herein.

FIG. 6A illustrates a series of substrate scan data collected by an endpoint sensor on a plurality of substrates using conventional techniques.

FIG. 6B illustrates a series of orientation dependent scan data collected by an endpoint sensor on a plurality of substrates using one or more of the processing techniques disclosed herein according to embodiments described herein.

FIG. 6C is a flowchart of a method of processing a substrate according to embodiments described herein.

FIG. 6D illustrates an example of orientation dependent scan data collected on a substrate according to embodiments described herein.

FIG. 6E illustrates a graph that includes a plurality of orientation dependent scan data collected as a function of scan data (or platen rotation) on a plurality of substrates, according to embodiments described herein.

FIG. 6F illustrates an example of substrate surface topography data collected from a model or measured on a substrate, according to embodiments described herein.

FIG. 6G illustrates an example of orientation dependent scan data collected on a substrate, according to embodiments described herein.

FIG. 6H illustrates plots of orientation dependent scan data collected using a respective scanned path illustrated in FIG. 6G on a substrate, according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

An apparatus and methods for reliably determining an endpoint of a chemical mechanical polishing (CMP) process are disclosed herein. The endpoint detection methods disclosed herein include the use of computer generated methods and supporting hardware to improve the determination of the endpoint of the CMP process.

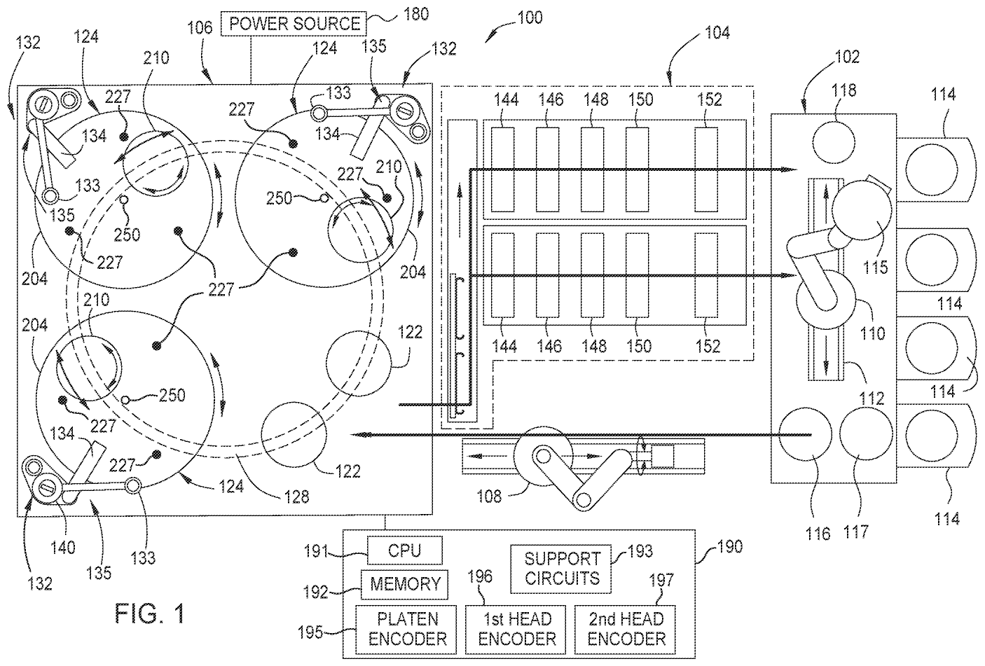

FIG. 1 is a top plan view illustrating one embodiment of a CMP system 100. The CMP system 100 includes a factory interface module 102, a cleaner 104, a polishing module 106, and a controller 190. A substrate 115, such as a silicon wafer with one or more layers deposited thereon, is processed within the CMP system 100 to polish the surface of the substrate 115.

A wet robot 108 is provided to transfer the substrates 115 between the factory interface module 102 and the polishing module 106. The wet robot 108 may also be configured to transfer the substrates 115 between the polishing module 106 and the cleaner 104. The factory interface module 102 includes a dry robot 110 which is configured to transfer the substrates 115 between one or more cassettes 114, one or more transfer platforms 116, one or more metrology stations 117, and one or more pre-aligner stations 118 of the factory interface 102. Substrates 115 are loaded into the CMP system 100 via the cassettes 114. In one embodiment depicted in FIG. 1, four substrate storage cassettes 114 are shown. The dry robot 110 within the factory interface 102 has sufficient range of motion to facilitate transfer between the four cassettes 114 and the one or more transfer platforms 116. Optionally, the dry robot 110 may be mounted on a rail or track 112 to position the robot 110 laterally within the factory interface module 102. The dry robot 110 additionally is configured to receive the substrates 115 from the cleaner 104 and return the clean polished substrates to the substrate storage cassettes 114.

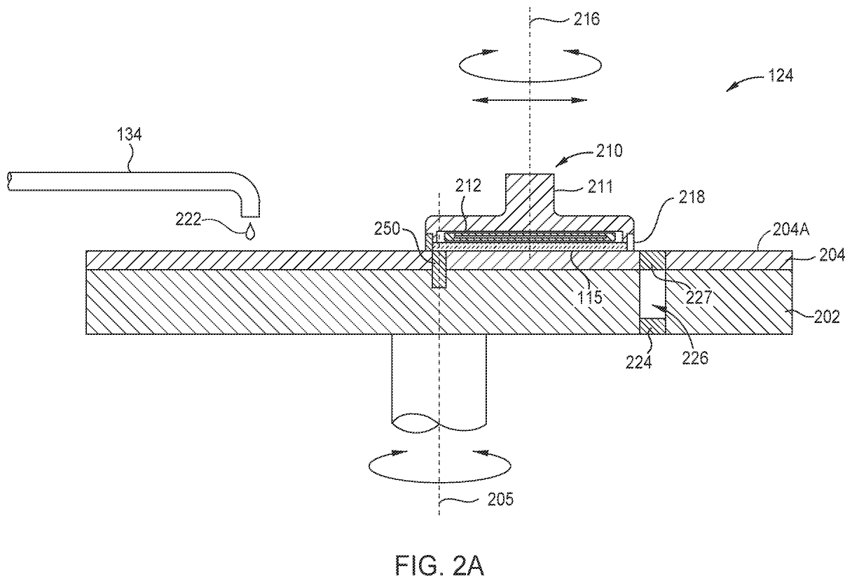

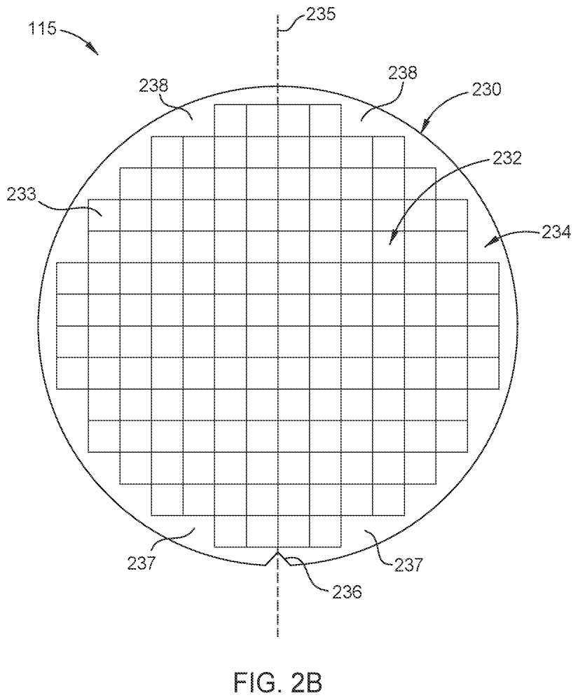

FIG. 1 shows an exemplary polishing module 106 that includes a plurality of polishing stations 124 on which the substrates 115 are polished while being retained in a carrier head 210 (e.g., polishing head). Each polishing station 124 includes a conditioning assembly 132 and a polishing fluid delivery module 135. While the polishing module 106 is shown having three polishing stations 124, the polishing module 106 may have more than three polishing stations 124. For example, the polishing module 106 may have a two pairs of polishing stations 124, each pair of stations 124 processing a substrate 115 independently of the other pair. The polishing stations 124 are sized to interface with one or more carrier heads 210 to facilitate polishing the substrate 115. The carrier heads 210 are coupled to a carriage (not shown) that is mounted to an overhead track 128 that is shown in phantom in FIG. 1. The overhead track 128 allows the carriage to be selectively positioned around the polishing module 106 which facilitates positioning of the carrier heads 210 selectively over the polishing stations 124 and the load cup 122. In the embodiment depicted in FIG. 1, the overhead track 128 has a circular configuration which allows the carriages retaining the carrier heads 210 to be selectively and independently rotated over and/or clear of the load cups 122 and the polishing stations 124. Additionally, the overhead tracks 128 facilitate the carriage sweeping the rotating carrier heads 210 relative to a polishing station 124 during polishing. The polishing stations 124 will be described in greater detail in relation to FIG. 2.

Each polishing station 124 includes a polishing pad 204 having a polishing surface (e.g., a polishing surface 204A in FIG. 2) capable of polishing a substrate 115. Each polishing station 124 includes a conditioning assembly 132 and a polishing fluid delivery module 135. In one embodiment, the conditioning assembly 132 may comprise a pad conditioning assembly 140 which dresses the polishing surface of the polishing pad 204 by removing polishing debris and opening the pores of the polishing pad 204 by use of a pad condition disk 133. In another embodiment, the polishing fluid delivery module 135 may comprise a fluid delivery arm 134 to deliver a slurry. In one embodiment, each polishing station 124 comprises a pad conditioning assembly 132. In one embodiment, the fluid delivery arm 134 is configured to deliver a fluid stream (e.g., a slurry 222 in FIG. 2) to a polishing station 124. The polishing pad 204 is supported on a platen (e.g., a platen 202 in FIG. 2) which rotates the polishing pad 204 during processing. Each polishing station 124 includes a polishing pad 204 secured to a rotatable platen 202. Different polishing pads 204 may be used at different polishing stations 124 to control the material removal of the substrate 115.

At least one load cup 122, such as the two load cups 122 shown in FIG. 1, is near the lower right corner of the polishing module 106 between the polishing stations 124 closest to the wet robot 108. The load cups 122 may serve multiple functions, including washing the carrier head 210, receiving the substrate 115 from the wet robot 108, washing the substrate 115, and loading the substrate 115 into the carrier heads (e.g., a carrier head 210 in FIG. 2).

The substrate 115 typically has a reference mark, such as a notch, flat edge, or other type of feature that can be used to identify crystalline orientations of the substrate 115 and note a rotational orientation of a front surface of the substrate 115 relative to a central axis. In certain embodiments, the factory interface module 102 can also include a pre-aligner 118 to position the substrate 115 in a known and desirable rotational orientation. The pre-alignment of the substrate 115 to a desired rotational orientation allows the substrate 115 to then be transferred to a substrate supporting surface within the load cup 122 and be positioned thereon in a known position and rotational orientation relative to the components in the CMP system 100. Thus, the carrier head 210 is then able to retrieve the substrate 115 at a known rotational orientation relative to the carrier head 210. For example, the pre-aligner 118 may include a reference mark detection system, such as an optical interrupter sensor (not shown), to sense when the reference mark is at a specific angular position.

In certain embodiments, the substrate 115 is placed in the metrology station 117 by the dry robot 110 prior to placing the substrate 115 on the transfer platform 116. For example, the dry robot 110 may transfer the substrate 115 from the pre-aligner 118 to the metrology station 117. The metrology station 117 is used to measures various aspects of the substrate 115. The metrology station 117 may use an optical, eddy current, resistive, or other sensors to measure the substrate 115. For example, the metrology station 117 may measure a thickness of the upper layer on the patterned surface of the substrate 115 by use of an eddy current sensor for conductive films and an optical sensor for dielectric films. The controller 190 receives the measurements which may be used to facilitate processing the substrate 115 within the CMP system 100. The dry robot 110 may transfer the substrate 115 to the transfer platform 116 after the substrate 115 is measured in the metrology station 117.

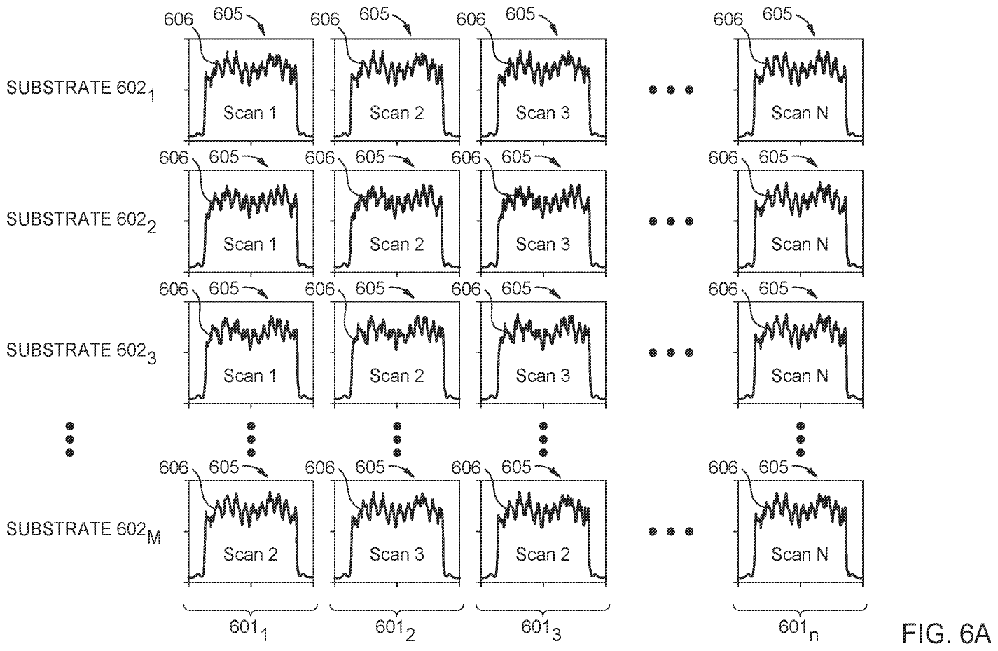

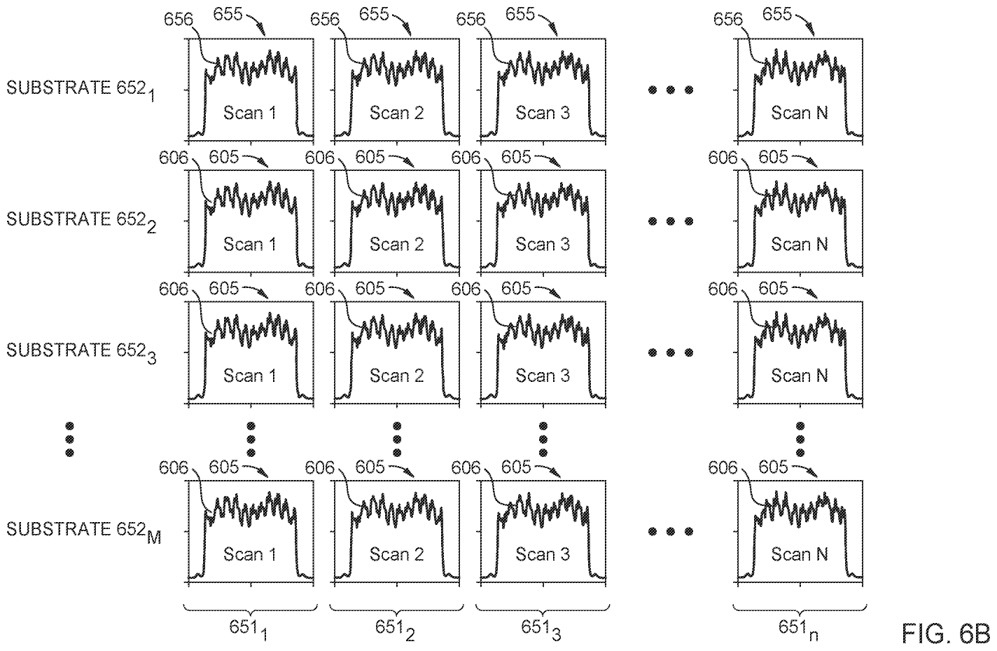

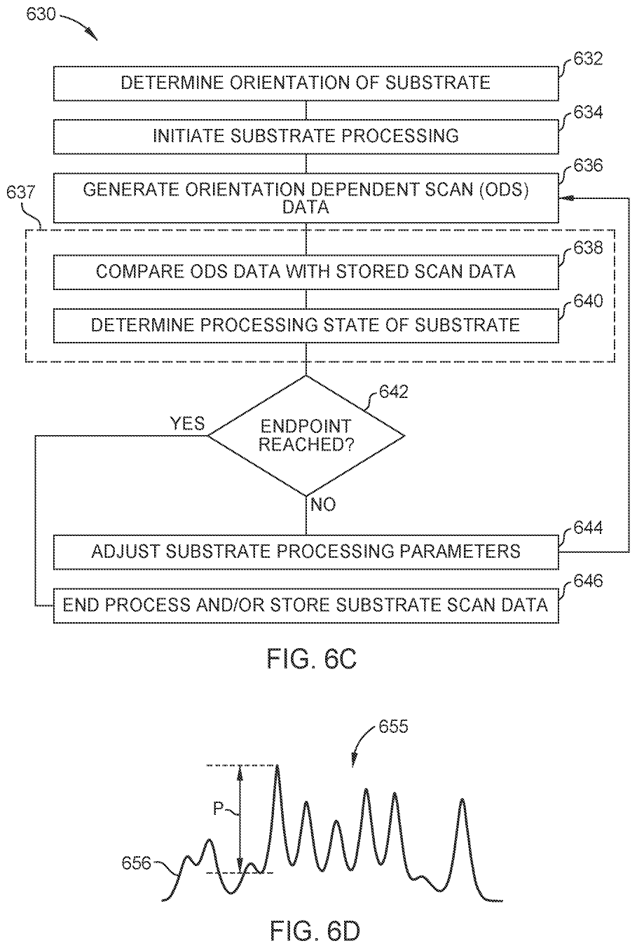

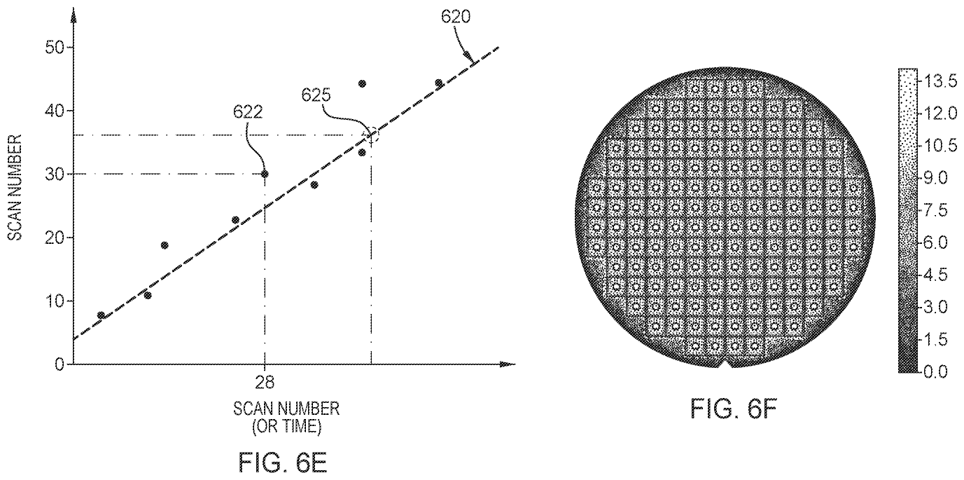

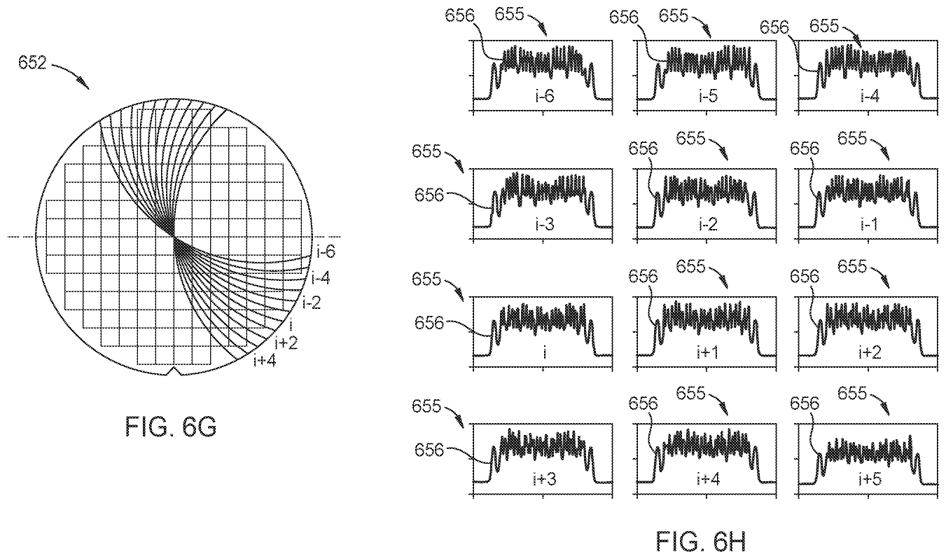

In some embodiments, the data collected within the metrology station 117 can be used to determine and/or, by use of the controller 190, form a model of the topography of the film disposed on the surface of the substrate. An example of a topography of a patterned substrate signal is illustrated in FIG. 6F. Therefore, as discussed further below, by correlating the topography of the film information received from the metrology station 117 with the known orientation of the reference mark on the substrate, the controller 190 can use the film topography information and the collected endpoint sensor data, which is also referenced to the reference mark on the substrate, to reliably know how the polishing process in one or more portions of the substrate surface is progressing towards an endpoint and if a CMP endpoint has been reached.

The wet robot 108 is configured to transfer the substrate 115 from the transfer platform 116 to one of the load cups 122. A rinsed-clean carrier head 210 is moved above the load cup 122 with the unpolished substrate 115. The unpolished substrate 115 is thereafter chucked to the carrier head 210, which then moves to a position above the pad 204 of a polishing station 124 to begin the CMP process.

The controller 190 controls aspects of the CMP system 100 during a CMP process (e.g., polishing process, polishing operation, polishing). In certain embodiments, the controller 190 is one or more programmable digital computers executing digital control software. The controller 190 can include a CPU (e.g., processor) 191 situated near the polishing apparatus, e.g., a programmable computer, such as a personal computer. The controller can include a memory 192 and support circuits 193. The controller 190 can, for example, coordinate rotation of the polishing pad 204 and the carrier head 210 to perform the desired CMP process and to facilitate monitoring for the endpoint of the CMP process. The CMP process system 100 is powered by power source 180, such as an electric power source configured to supply electric power to the components of the CMP process system 100.

Herein, the memory 192 is in the form of a computer-readable storage media containing instructions (e.g., non-volatile memory), that when executed by the CPU, facilitates the operation of the CMP process system 100. The instructions in the memory are in the form of a program product such as a program that implements the methods of the present disclosure (e.g., middleware application, equipment software application, etc.). The program code may conform to any one of a number of different programming languages. In one example, the disclosure may be implemented as a program product stored on computer-readable storage media for use with a computer system. The program(s) of the program product define functions of the embodiments (including the methods and operations described herein). Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The platen 202 and the carrier head 210 each have a rotation sensor such as an encoder, to determine their rotational position during the CMP operation. As shown in FIG. 1, a platen encoder 195, a first head encoder 196, and a second head encoder 197 are communicatively coupled to the controller 190. The platen encoder 195 is configured to determine the rotational (e.g., angular) orientation of the platen 202 and the pad 204. The first head encoder 196 is configured to determine the rotational orientation of each carrier head 210. The second head encoder 197 is configured to determine the location of each carrier head 210 above the polishing pad 204 (e.g., along the sweep path 302 of the carrier head 210 in FIG. 3). Thus, the controller 190 is able to determine and track the rotational orientation of the carrier head 210 with respect to the platen 202 during the CMP process. In some embodiments, each carrier head 210 has its own dedicated first and second head encoders 196, 197. In further embodiments, the controller 190 may calculate a rotation rate of the carrier head 210 and/or platen 202 and polishing pad 204 using the encoder and an internal timing element.

The substrate 115 may be polished in one or more of the polishing stations 124. For example, a carrier head 210 may retrieve an unpolished substrate 115 from the substrate supporting surface (not shown) in the load cup 122. Based on the known orientation and rotational position data received from first head encoder 196 and the physical position from the data received from the second head encoder 197, the position of the substrate relative to the platen 202 and the carrier head 210 is known during CMP processing. The carrier head 210 and substrate 115 chucked thereto are then moved to a first polishing station 124, such as the polishing station 124 in the upper right corner of the polishing module 106 closest to the cleaner 104. The substrate 115 is then subjected to a CMP polishing operation on the first polishing station 124, such as removing a first layer formed on the substrate 115. Once the substrate 115 is done polishing in the first polishing station 124, then the carrier head 210 moves the substrate 115 to a second polishing station 124 (e.g., the polishing station 124 in the upper left corner of the polishing module 106) for additional CMP polishing. For example, the second polishing station 124 may polish the surface of the substrate 115 to form trench lines of a desired height. In some embodiments, the carrier head 210 and substrate 115 may optionally be transferred from the second polishing station 124 to a third polishing station 124 (e.g., the polishing station 124 in the lower left corner of the polishing module 106) to subject the substrate 115 to additional polishing.

After polishing, the carrier head 210 moves the polished substrate 115 chucked thereto above a load cup 122 where the polished substrate 115 is thereafter placed into the substrate supporting surface of the load cup 122. The wet robot 108 transports the polished substrate 115 from the substrate supporting surface of the load cup 122 to a cleaning chamber in the cleaner 104, where slurry residues and other contaminants that have accumulated on the substrate's 115 surface during polishing are removed. In the embodiment depicted in FIG. 1, the cleaner 104 includes two pre-clean modules 144, two megasonic cleaner modules 146, two brush box modules 148, two spray jet modules 150, and two dryers 152. The dry robot 110 then removes the substrate 115 from the cleaner 104. In some embodiments, the dry robot 110 transfers the substrate 115 to the metrology station 117 to be measured again. In certain embodiments, the post-polish measurements can be used to adjust the polishing process parameters for a subsequent substrate. Finally, the dry robot 110 returns the substrate 115 to one of the cassettes 114.

FIG. 2A illustrates a schematic cross-sectional view of a polishing station 124 of the CMP system 100 of FIG. 1. As shown, the polishing station 124 further includes a plurality of endpoint detection sensors 224 and optionally an orientation sensor 250. A substrate 115 disposed in the carrier head 210 is shown engaged with the polishing surface 204A of the pad 204 that is coupled to the platen 202.

FIG. 2B is a top view of the substrate 115 to illustrate the front surface 230 of the substrate 115 that is engaged with the polishing pad 204 during polishing. The front surface 230 includes a patterned portion 232 and a non-patterned portion 234. The patterned portion 232 (e.g., patterned surface) is the portion of the substrate 115 were a plurality semiconductor devices are formed within a semiconductor die during one or more prior processes. As shown, the patterned portion 232 is divided into a plurality of full dies 233 arranged in a grid-pattern. Each die 233 includes a plurality of semiconductor devices being formed on the substrate 115. For example, the semiconductor devices include one or more layers formed by one or more processes, such as through physical vapor deposition (PVD), chemical vapor deposition (CVD) or atomic layer deposition (ALD).

The non-patterned portion 234 is the portion of the front surface 230 around the patterned portion 232. Semiconductor devices are not formed on the non-patterned surface 234. The non-patterned portion 234 may be exposed to the same processing environments that forms the patterned portion 232. Materials, such as barrier metals, may be deposited on the non-patterned surface 234 while the semiconductor devices are formed on the patterned portion 232. In some embodiments, the non-patterned portion 234 may be a partially patterned portion that includes only partial, and not full, dies. The surface area of the non-patterned portion 234 may not be uniform around the patterned portion 232. As shown in FIG. 2B, the surface area of the non-patterned surface 234 fluctuates around the patterned portion 232 depending on the shape of the patterned portion 232. Thus, there are portions of the non-patterned surface 234 with a surface area greater than other portions.

The substrate 115 includes a reference mark 236 (e.g., wafer notch) at the edge of the substrate 115 and thus at the edge of the non-patterned portion 234. The reference mark 236 is a fixed feature formed on the substrate 115 depending on the doping type and crystalline orientation of the substrate 115. While the reference mark 236 is shown as a v-shaped notch formed on the edge of the substrate 115 in FIG. 2B, the reference mark 236 may be another feature. For example, the reference mark 236 may be one or more flat edges of the substrate 115.

The substrate 115 has a first line of symmetry 235 that passes through the center of the reference mark 236. The non-patterned surface 234 is generally symmetrical about this first line of symmetry 235. Thus, there is a first region 237 on either side of the line of symmetry 235 adjacent to the reference mark 236 that has substantially the same surface area. Additionally, there is a similar pair of second regions 238 on the opposite edge of the substrate 115 as the reference mark 236 that has a similar surface area as the first region 237. While the non-patterned surface 234 may be generally symmetric about the first line of symmetry 235, the circuits formed in the individual dies 233 of the patterned surface 232 may or may not be symmetric about this first line of symmetry 235.

Referring back to FIG. 2A, the polishing pad 204 is secured to the platen 202, such as being secured using an adhesive, such as a pressure sensitive adhesive (PSA) layer (not shown), disposed between the polishing pad 204 and the platen 202. The carrier head 210, facing the platen 202 and the polishing pad 204 mounted thereon, includes a flexible diaphragm 212 configured to impose different pressures against a backside surface of a substrate 115 that is disposed between the carrier head 210 and the polishing pad 204. This flexible diaphragm 212 is also configured to chuck the substrate 115 to the carrier head 210 to allow the carrier head 210 to move the substrate 115 around the polishing module 106. The carrier head 210 includes a carrier ring 218 surrounding the substrate 115 which holds the substrate 115 within the head 210 during polishing. The carrier head 210 rotates about a carrier head axis 216 while the flexible diaphragm 212 urges the front surface 230 (FIG. 2B) of the substrate 115 against the polishing surface 204A of the polishing pad 204. During polishing, a downforce on the carrier ring 218 urges the carrier ring 218 against the polishing pad 204 to improve the polishing process uniformity and prevent the substrate 115 from slipping out from under the carrier head 210. In certain embodiments, the carrier head 210 includes a shaft 211 which has an axis that is colinear with carrier head axis 216. In further embodiments, the platen 202 and the carrier head 210 each have a mechanism or motor (not shown) driving their rotation.

In some embodiments, the platen 202 and polishing pad 204 both rotate about a common platen axis 205. In some embodiments, the polishing pad 204 rotates in the same rotational direction as the rotation direction of the carrier head 210. For example, the polishing pad 204 and carrier head 210 both rotate in a counter-clockwise direction. The polishing pad 204 and carrier head 210 may be rotated at the same or different speed during a polishing operation. As shown in FIG. 2A, the polishing pad 204 has a surface area that is greater than the front surface 230 of the substrate 115. However, in further embodiments, the polishing pad 204 has a surface area that is less than the surface area of the front surface 230 of the substrate 115.

FIG. 2A also shows an exemplary embodiment of one of the endpoint detection sensors 224. Each endpoint detection sensors 224 is positioned radially from the platen axis 205. The endpoint sensor 224 is disposed in a platen opening 226 formed in the platen 202 and beneath an endpoint detection features 227 (e.g., optically transparent window) of the polishing pad 204. The endpoint detection sensor 224 directs light through the platen opening 226 and endpoint detection feature 227 at the front surface 230 of the substrate 115 to detect properties of the front surface 230 as the endpoint sensor 224 passes beneath the substrate 115 during polishing. The controller 190 uses the data collected by the endpoint detection sensors 224 to determine when the endpoint of the CMP process is reached. The endpoint may be, for example, when a desired thickness of a layer formed on the patterned surface 232 is reached. For example, the endpoint may be reached when the metal in a plurality of trench lines formed on the patterned portion 232 reaches a desired thickness.

While the endpoint detection sensor 224 is shown as an optical sensor, the endpoint sensor 224 may be any other suitable sensor capable of monitoring changes in the patterned portion 232 during the CMP process. For example, the endpoint sensor 224 may be an eddy current sensor or an inductive current sensor. The eddy current sensor and inductive current sensor may be embedded in the platen 202 and/or pad 204, and the endpoint detection features 227 (e.g., optically transparent window) and opening 226 may be omitted or replaced by an electromagnetic field transparent window. While the polishing station 124 is shown having three endpoint detection sensors 224 disposed around an optional orientation sensor 250, as evidenced by the three endpoint detection features 227 in FIG. 1, the polishing station 124 may include less than or more than three endpoint sensors 224.

Each endpoint detection sensor 224 is positioned at a fixed distance from the rotational center (e.g., platen axis 205) of the platen 202. The platen encoder 195 tracks the rotational position of the platen 202 and pad 204. The controller 190 is able to determine the location of the endpoint sensor 224 as the platen 202 rotates based on the fixed location of the endpoint sensor 224 and the rotational information obtained from the platen encoder 195.

### Substrate Orientation Information

As discussed above, by use of the pre-aligner 118, robot 108 and controller 190 a substrate can be positioned on a substrate supporting surface of the load cup 122 in a known orientation so that the orientation of the substrate 115 relative to an orientation of the carrier head 210 and an orientation of a platen 202 and pad 204 are known and can be monitored and controlled during processing within the CMP system 100. However, in some processing methods, it may be desirable confirm and/or determine the orientation of the substrate 115 relative to the orientation of the carrier head 210 and the orientation of a platen 202 and pad 204. The orientation of the substrate 115 relative to the orientation of the carrier head 210 and the orientation of a platen 202 and pad 204 can optionally be determined after performing a polishing process on a different platen 202 and pad 204 from where the subsequent polishing process is to be performed by use of the orientation sensor 250 and controller 190. In one example, the controller 190, carrier head 210 and orientation sensor 250 is used confirm and/or determine the orientation of the substrate 115 before the substrate is processed on the platen 202 and pad 204 in the second polishing station 124 (e.g., middle polishing station 124 in FIG. 1), after being processed in the first polishing station 124 (e.g., top-right polishing station 124 in FIG. 1).

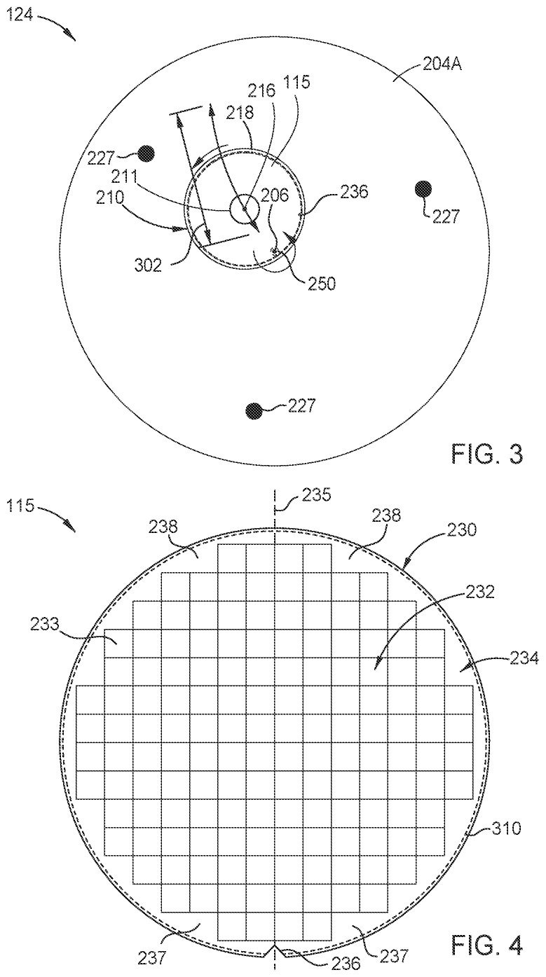

FIG. 2A also shows the orientation sensor 250. As will be discussed in relation to FIGS. 3 and 4, the orientation sensor 250 is optionally used to locate the reference mark 236 in-situ so that the controller 190 can determine the rotational orientation of the substrate 115 relative to the carrier head 210 and the pad 204. The controller 190 is able to correlate the ascertained location of the reference mark 236 with respect to the rotational orientation of the carrier head 210 since the substrate 115 is rotating with the carrier head 210. The orientation sensor 250 is used to ascertain and/or confirm the substrate's 115 rotational orientation after the substrate 115 is transferred to a polishing station 124 from a different polishing station 124. In other words, the substrate 115 does not have to be removed from the polishing module 106, passed through the cleaner 104, and placed into the pre-aligner 118 or metrology station 117 to ascertain the rotational orientation of the substrate 115 prior to polishing substrate 115 on a second or third polishing station 124.

Knowing the rotational orientation of the substrate 115 and carrier head 210 and the location of each endpoint sensor 224 during polishing allows the controller 190 to ascertain which part of the front surface 230 of the substrate 115 is being scanned by a particular endpoint sensor 224. In other words, the controller 190 can correlate the position and orientation of the substrate 115 with the position of each endpoint sensor 224 during the polishing process.

The orientation sensor 250 is located at the rotational center of the platen 202 such that the rotational axis of the sensor 250 is collinear with the platen axis 205. The endpoint sensors 224 are arranged around the orientation sensor 250 and orbit around the platen axis 205 as the platen 202 rotates. To find the reference mark 236, the carrier head 210 is moved to a scan position as shown in FIG. 2A (see also FIG. 3) to place the edge of the substrate 115 above the orientation sensor 250. This allows the orientation sensor 250 to scan the edge of the substrate 115 to locate the reference mark 236. In some embodiments, the orientation sensor 250 scans the edge of the substrate 115 as the carrier head 210 makes one or more complete revolutions around the carrier head axis 216 in order to find the reference mark 236. In other embodiments, the reference mark 236 is located after only a partial revolution of the carrier head 210.

In some embodiments, and as shown in FIG. 2A, the orientation sensor 250 is an isotropic electromagnetic sensor. In some embodiments, the orientation sensor 250 is an eddy current sensor, an optical sensor, or other sensor capable of detecting the reference mark 236. As shown, the orientation sensor 250 is partially embedded in both the platen 202 and the pad 204. In some embodiments, the orientation sensor 250 is only embedded in the platen 202 and is covered by the pad 204.

In some embodiments, a layer of material formed on the surface of the substrate partially or fully covers the front surface 230, with both the patterned portion 232 and non-patterned portion 234 being fully or partially covered by the layer. This layer may be deposited to form another layer or feature on the dies 233 of the patterned portion 232 that will be polished down in the CMP system. The orientation sensor 250 is still able to scan the edge of the substrate 115 to locate the reference mark 236 even if a layer is deposited over both the patterned portion 232 and the non-patterned portion 234. For example, the orientation sensor 250 may obtain data that shows the part of the layer scanned by the orientation sensor 250 was over the underlying patterned portion 232 or non-patterned portion 234. In other words, the controller 190 can differentiate between the patterned portion 232 and non-patterned portion 234 even if both are at least partially obscured by the same layer. Additionally, the data obtained by the orientation sensor 250 can show variations in the material being scanned, such as variations in the area of the non-patterned portion 234, even if a layer is fully or partially covering the front surface 230.

FIG. 3 illustrates a top schematic plan view of the polishing station 124 to show the carrier head 210 in the scan position to find the reference mark 236. The conditioning assembly 132 and the polishing fluid delivery module 135 are omitted. The head 210 is moveable relative to the pad 204 along a sweep path 302 to sweep the substrate 115 along the polishing surface 204A during the polishing process. The endpoint sensors 224 cross the sweep path 302 as the platen 202 rotates. The endpoint sensors 224 pass beneath the substrate 115 when the carrier head 210 places the substrate 115 at one or more positions along the sweep path 302 that is in the travel path of the endpoint sensors 224 as the platen 202 rotates.

The carrier head 210 is shown in a scan position with the edge of the front surface 230 being at least partially positioned above the orientation sensor 250. The carrier head 210 is rotated relative to the orientation sensor 250 and the platen 202 while the orientation sensor 250 makes a scan of the substrate 115 edge to locate the reference mark 236. The carrier head 210 is moved to the scan positon after the substrate 115 is transferred to a polishing station 124 from a different polishing station 124 in the polishing module 106 to allow a scan 310 (see FIG. 4) to be taken of the front surface 230 to ascertain the rotational orientation of the substrate 115.

FIG. 4 illustrates the scan 310 of a region of the front surface 230 of the substrate 115 by the orientation sensor 250. The scan 310 (i.e., illustrated by the dashed line) illustrates the path where the orientation sensor 250 passes across the edge region of the front surface 230 of the substrate to collect data as the carrier head 210 rotates the substrate 115 relative to the orientation sensor 250. The scan 310 is made near the edge of front surface 230. The scan 310 is made close enough to the edge of the substrate 115 such that the scan 310 passes through part of the reference mark 236. In some embodiments, the orientation sensor 250 makes a scan 310 below only the non-patterned surface 234 when the carrier head 210 is in the scan position. Alternatively, the orientation sensor 250 may complete a scan 310 along that edge of the substrate 115 that passes across both the patterned surface 232 and the non-patterned surface 234.

The orientation sensor 250 collects data about the front surface 230 along the scan 310. This data is sent to the controller 190 for analysis to determine the location of the reference mark 236. The first head encoder 196 simultaneously records the rotational position of the carrier head 210 while the orientation sensor 250 collects data along the scan 310. The controller 190 correlates the data obtained from the orientation sensor 250 with the rotational position of the carrier head 210 for which the data was obtained. In other words, the controller 190 is able to match the data obtained from the orientation sensor 250 with the rotational positon of the carrier head 210. This allows the controller 190 to analyze the data to determine the location of the reference mark 236 in relation to the rotational orientation of the carrier head 210. Once the location of the reference mark 236 relative to the carrier head 210 is known, then the rotational orientation of the substrate 115 is known.

In some embodiments, the carrier head 210 makes just one revolution about the carrier head axis 216 for the orientation sensor 250 to collect sufficient data along the scan 310 to determine the location of the reference mark 236. In other embodiments, the carrier head 210 makes more than one complete revolution to collect sufficient data along the scan 310 to determine the location of the reference mark 236.

In some embodiments, the platen 202 and the carrier head 210 both rotate as the orientation sensor 250 scans the substrate 115. In other embodiments, the platen 202 remains stationary while the carrier head 210 is rotated to allow the orientation sensor 250 to scan the substrate 115. The controller 190 may cause the platen 202 to begin rotating to start the CMP process once the rotational orientation of the substrate 115 is ascertained.

During a CMP process, the controller 190 uses the information gathered from the platen encoder 195, first head encoder 196, and second head encoder 197 to determine and track the position of the carrier head 210 relative to the platen 202. In other words, the controller 190 knows where the carrier head 210 is above the rotating platen 202 at any given point in time, including knowing the rotational orientation of the carrier head 210 relative to the platen 202. Once the controller 190 ascertains the rotational orientation of the substrate 115 relative to the carrier head 210, then the controller 190 similarly knows the rotational orientation and position of the substrate 115 relative to the rotating platen 202 and endpoint sensors 224 at any given point in time of the polishing process.

The controller 190 uses the positional information of the substrate 115 and platen 202 to determine which portions of the front surface 230 are scanned by each endpoint sensor 224 during the endpoint analysis. In other words, since the position and rotational orientation of the substrate 115 relative to the head 210 and platen 202 is known, the controller 190 is able to correlate the data collected by the endpoint sensors 224 to a known location on the front surface 230. The sweep position of the head 210 relative to the platen 202 and the rotation of both the carrier head 210 and platen 202 may be coordinated such that each endpoint sensor 224 traverses the same scan path multiple times during the CMP process to scan the same area (e.g., same region) of the front surface 230. Obtaining data from the same area over the substrate repeatedly improves the signal to noise ratio of the data obtained by the endpoint sensors 224 since a consistent signal will be obtained by the endpoint sensor 224 at each scan that reflects the progression of the polishing process over time. Improving the signal to noise ratio improves the endpoint analysis, allowing for a more accurate determination of when the endpoint is reached to produce a desired and uniform polish across the patterned surface 232.

In conventional CMP processes, the orientation of the substrate 115 is not known after the transfer to the second polishing station 124. As a result, the controller does not know what parts of the substrate are being scanned during the endpoint analysis because the collected data cannot be correlated with a known location on the surface of the substrate. An example of substrate scan data collected for a series of substrates using convention techniques is illustrated in FIG. 6A. FIG. 6A includes a plurality of measurements, referred to herein as substrate scan data 605, which has been collected for a plurality of substrates 602. The substrates 602 are each a substrate 115. Each of the collected substrate scan data 605, which is created as the endpoint sensor 224 traverses a path across the surface of the substrate, includes film property information that is detected by the endpoint sensor 224 and is illustrated by the curve 606. In this example, the plurality substrates 602 includes M number of substrates, where M varies from 1 to M, and M is at least greater than one (e.g., M is greater than three in FIG. 6A). Also, as illustrated in FIG. 6A, during processing each substrate 602 is scanned a plurality of times. The number of scans 601 can include N number of scans that each provide substrate scan data 605, where N varies from 1 to N, and N is at least greater than one (e.g., N is greater than three in FIG. 6A). Due to the lack of knowledge regarding the orientation of the substrate 602 relative to the orientation of the carrier head 210 and an orientation of a platen 202 and pad 204 the detected film property information in each collected substrate scan data 605 will differ as the endpoint sensor 224 traverses a path across different and unknown portions of the surface of the substrate 602. As illustrated in FIG. 6A, each of the curves 606 in each of the collected substrate scan data 605 differs relative to each other in each successive scan 601₁, 601₂, 601₃ . . . 601_{N} and also for each successive substrate 602₁, 602₂, 602₃ . . . 602_{M}. Thus, the endpoint analysis in a conventional CMP process is based on random portions of the substrate 602 scanned by the endpoint sensors. It has been found that the endpoint detection process disclosed herein, and illustrated in FIGS. 6B-6H, improves the ability of the controller 190 to detect the endpoint of the CMP process.

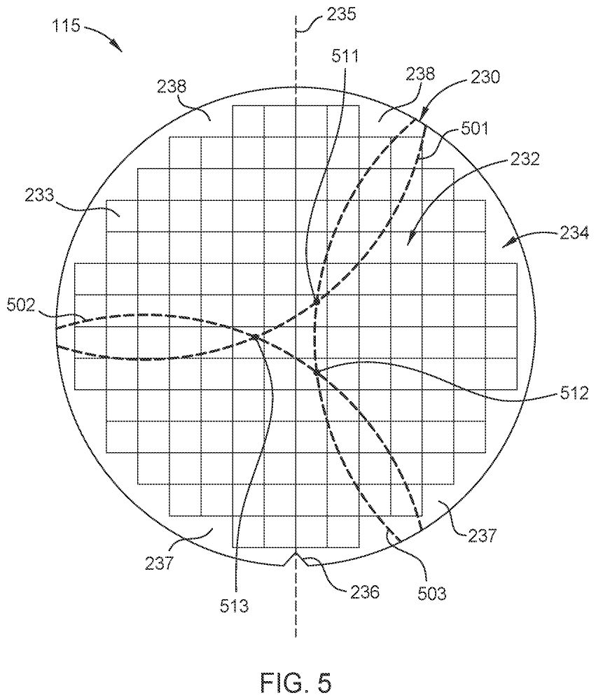

FIG. 5 illustrates the top view of substrate 115 shown in FIG. 2B showing an exemplary first endpoint scan path 501, an exemplary second endpoint scan path 502, and an exemplary third endpoint scan path 503 across the front surface 230. Each endpoint scan path 501, 502, 503 corresponds the path of a respective endpoint sensor 224 of the polishing station 124 shown in FIG. 3 (see windows 227) takes as it passes below the front surface 230 of a substrate 115. The endpoint sensor 224 generates a curve, such as curve 606 that is provided within the substrate scan data 605, as an endpoint sensor's scan path traverses across the front surface 230 of the substrate 115. As shown, each endpoint scan path is in the shape of an arc due to the motion of the carrier head 210 and the platen 202 during polishing. Each endpoint sensor 224 scans the outer surface along the respective endpoint scan path 501, 502, 503 multiple times (i.e., scans 601₁, 601₂, 601₃ . . . 601_{N}), during a CMP process to facilitate the endpoint analysis.

### Improved Endpoint Processing Apparatus and Methods

In some embodiments, by use of the apparatus and methods disclosed herein, the data obtained by the endpoint sensors 224 along known scan paths across the surface of the substrate is used during the endpoint analysis to create improved substrate scan data 655, which is used to better determine when the endpoint of the polish process has been reached. FIG. 6C illustrates a flow chart of an exemplary method 630 of processing a substrate using the improved substrate scan data 655 collected on one or more substrates. For clarity and ease of discussion purposes the improved scan data 655 is often referred to herein as orientation dependent scan data 655, or ODS data 655, to avoid confusion with substrate scan data 605 collected by use of conventionally configured systems and methods that do not monitor or use substrate orientation information during processing.

As is discussed further below, the ability to start with the known orientation of the substrate relative to the carrier head 210, platen 202 and pad 204 for similarly processed or patterned substrates in a batch, or batches of substrates, allows previously collected data from prior processed substrates to be used to more accurately determine the polishing process endpoint. Moreover, the controller 190 is able to use the positon and orientation of the substrate 115 to correlate the data obtained by an endpoint sensor 224 with each specific die 233 along the scan path of the endpoint sensor 224. Thus, the endpoint of the CMP process may be evaluated based one or more particular dies 233. In some embodiments, the controller 190 can use the known orientation of the substrate 115 to coordinate the carrier head 210 and platen 202 such the end point sensors 224 traverse the same scan path a plurality of times during the polishing of each substrate 115. In other words, the same portion of every substrate 115 may be scanned repeatedly by the endpoint sensors 224.

In some embodiments, the carrier head 210 and the substrate 115 may be placed in the same orientation relative to one another prior to starting a polishing process. In other words, each substrate 115 and carrier head 210 may be placed at the same starting position (e.g., starting orientation) with respect to the end point sensors 224 of the polishing pad 204 prior to starting the polishing operation of the substrate 115. For example, the carrier head 210 may be positioned in a first orientation when retrieving each substrate 115 positioned at a second orientation from a substrate retrieving surface within the CMP system 100, such as from a pre-aligner 118. The carrier head 210 then engages substrate 115 at a starting point on the polishing pad 204, with the endpoint sensors 224 being positioned at a third orientation. The ability to start with the same orientation of the substrate relative to the carrier head 210, platen 202 and pad 204 for similarly processed or patterned substrates in a batch, or batches of substrates, allows previously collected data from prior processed substrates to be used to more accurately determine the polishing process endpoint.

FIG. 6B illustrates a plurality of ODS data 655 that has been collected on a plurality of substrates 652. Each substrate 652 is a substrate 115. The orientation of each substrate 652 relative to the carrier head 210 is known. Each of the collected ODS data 655 includes film property information that was detected by the endpoint sensor 224. An example of film property information is illustrated by the curve 656 within the ODS data 655. In this example, the plurality substrates includes M number of substrates, where M varies from 1 to M, and M is at least greater than one (e.g., M is greater than three in FIG. 6B). Also, as illustrated in FIG. 6B, during processing each substrate 652 is scanned a plurality of times. The number of scans 651 can include N number of scans that each provide ODS data 655, where N varies from 1 to N, and N is at least greater than one (e.g., N is greater than three in FIG. 6B). Due to the known orientation of the substrate 652 relative to the orientation of the carrier head 210, platen 202 and pad 204 the detected film property information in each collected piece of ODS data 655 will typically include small or minor variations in the shape of the curve 656 as the endpoint sensor 224 traverses a path across the same portions of a surface of each of the substrates 652. As illustrated in FIG. 6B, each of the curves 656 in each of the collected ODS data 655 are substantially similar relative to each other in each scan 6511, 6512, 6513 . . . 651N for each successive substrate, as illustrated by the substantially same shaped curves 656 in each of the first scans 6511 for each substrate, each of the second scans 6512 for each substrate, each of the third scans 6513 for each substrate, and each of the N^{th} scans 651N for each substrate.

FIG. 6C depicts a method 630 of processing a substrate using the improved substrate scan data 655 collected on one or more substrates. The method 630 begins at operation 632, in which the orientation of a substrate 652 (e.g., substrate 115) is determined by one or more methods described herein. In one example, the orientation of the substrate 652 is determined by use the pre-aligner 118 and controller 190. After determining the orientation of the substrate 652, the substrate 652 is transferred by use of the controller 190, in a known orientation, to the load cup 122 and ultimately to the carrier head 210 that is additionally oriented in a known position and orientation due to the use of the first head encoder 196 and the second head encoder 197, respectively.

In an alternate example, the substrate 652 is transferred by use of the controller 190 to the load cup 122 and carrier head 210, which is oriented in a known position and orientation. Then, the orientation of the substrate 652 relative to the orientation of the carrier head 210 and the orientation of a platen 202 and pad 204 is determined by use of the orientation sensor 250, described above. The orientation sensor 250 may also be used to determine the orientation of the substrate 652 relative to a carrier head 210 when the substrate 652 is transferred to a subsequent polishing station, such as after the substrate 652 is transferred from the first polishing station to the second polishing station. During the orientation determining process performed by the orientation sensor 250, it may be desirable for no material or an insignificant amount of material to be removed from the surface of the substrate 652 before the orientation of the substrate 652 is determined relative to the carrier head 210, platen 202 and pad 204 to assure that each of the substrates 6521 to 652M will have a similar polishing process starting point. In some cases, it may be desirable for the controller 190 to start a CMP process after the substrate 652, carrier head 210 and/or platen 202 are all aligned and oriented in a known or the same starting position and orientation relative to each other to assure that the scan paths across the substrate surface for each successive substrate 652 are substantially the same.

Next at operation 634, the substrate 652 is polished on a pad 204 coupled to a platen 202 of a polishing station 124, such as the first polishing station. The polishing process includes urging the front surface 230 of the substrate 652 against the surface of the pad 204 while a slurry and/or other chemicals are provided to the substrate surface. During the polishing process the diaphragm 212 within the carrier head 210 urges the substrate 652 against the surface of the pad 204. The carrier head 210 and platen 202 may be coordinated such that at least one desired portion of the front surface of the substrate 652, such as a desired scan path, is repeatedly scanned an endpoint sensor 224.

Next at operation 636, one or more endpoint sensors 224 generate ODS data 655 by detecting film property information as the endpoint sensor 224 traverses a path across the surface of the substrate. Due to the known orientation of the substrate 652 relative to the orientation of the carrier head 210, platen 202 and pad 204 the detected film property information in each collected piece of ODS data 655 generated by the one or more endpoint sensors 224 will typically include small or minor variations in the shape of the curve 656. However, due to differences in substrate size, for example, the position of the scan paths across the substrate surface may vary slightly from one substrate to the next, which will cause slight variations in the curves 656 in each of the collected ODS data 655 in a series of scans from substrate-to-substrate. The error or variation in the collected ODS data 655 from each successive scan can thus cause a drift in scan path over the substrate over time, which can be resolved by one or more of the techniques described below.

Next at operation 637, the generated ODS data 655 is analyzed to determine whether the polishing process has reached its endpoint. Operation 637 includes an operation 638 that compares the generated ODS data 655 with information stored in the memory of the controller 190. The information stored in memory can include a library of ODS data 655 collected from prior polishing process runs on prior processed substrates (e.g., first substrate in a batch), calibration substrate data collected from specially processed substrates that are used to determine the desired ODS data 655 sequence to achieve the endpoint of the polishing process, or modelling data generated based on information known about the polishing process and substrates that are to be processed.

In some embodiments, during operation 638 the controller 190 is used to find a substantial match between the curve 656 in a recently generated ODS data 655 and information stored in memory (e.g., prior stored curve 656 data). In some cases, the matching process may include a comparison between a portion of the curve 656 in the recently generated ODS data 655 and the same portion of each of the curves 656 stored in memory to determine if there is a match between the curves. In some embodiments, by monitoring the current time, number of scans, or number of rotations of the platen 202, the number of curves that need to be analyzed to determine if there is match can be reduced to only a small number of curves that have been stored around the current time during the current CMP process in which the recently generated ODS data 655 was measured.

Operation 637 also includes an operation 640 which compares an attribute of a portion of the curve 656 of the recently generated ODS data 655 with an attribute of a portion of the substantially matching stored information (e.g., prior stored curve 656 data) to determine the current state of the polishing process that is being performed on the substrate 115. In one example, to determine status of the CMP process the comparison can include determining peak-to-peak variation information within a portion of the curve 656 in the recently generated ODS data 655, such as the thirtieth scan 65130 of the substrate, with peak-to-peak variation information found in the matching information stored in memory, such as peak-to-peak variation information relating to a thirtieth scan 65130 of a previously processed substrate. FIG. 6D illustrates a measured peak-to-peak variation “P” within a desired portion of a curve 656 of a generated ODS data 655 that can be compared with the information stored in the memory of the controller 190, such as the same portion the curves 656 stored in memory. Therefore, by comparing the attribute of the portion of the curve 656 with the same attribute of the portion of the substantially matching stored information the deviation in the compared attributes (e.g., difference in the heights of the peak-to-peak variation “P”) can be used in a subsequent operation to adjust one or more of the CMP processing parameters (e.g., time, pressure, rotation speed(s), etc.) to achieve the endpoint of the CMP process.

FIG. 6E, illustrates a plot of the relative measured peak-to-peak variation “P” for one or more prior processed substrates 652 as a function of the number of scans (or time) performed on the current substrate (X-axis) versus the number of scans for the data stored in memory (Y-axis), where it has been determined by further analysis or testing that an endpoint for a certain substrate type has been reached at a point 625. Referring to FIG. 6E, in one example, after 28 scans are performed on the currently processed substrate 652, it is determined that the measured attribute of the generated ODS data 655 matches with an attribute of curve 656 data stored in memory that achieved a similar result after 30 scans were performed (e.g., point 622). In this case, the polishing process being performed on the currently processed substrate 652 is farther along than a nominal polishing process, which is within the library of comparison data stored in memory of the controller 190. In the case where the data stored in memory for a nominal polishing process exactly matches the scan data that is being generated on the current substrate that is being processed, the slope of the peak to peak variation data will be equal to a 1:1 slope, as illustrated by the linear curve 620.

In some embodiments, the library of comparison ODS data may be specific to a polishing station. For example, the controller 190 may have a first library of ODS data for the first polishing station, a second library of ODS data for the second polishing station, and third library of ODS data for the third polishing station. The difference in the library may be due to the difference in the polishing process being performed on at the station.

Next at operation 642, based on the comparison of the measured attributes of the current substrate 652 and the matching stored substrate the controller 190 decides whether the endpoint has been reached. The endpoint is thus determined by determining that the attribute measured on the current substrate 652 similarly matches an attribute of a substrate that had achieved a desired endpoint. For example, the controller 190 may determine that the ODS data 655 obtained during a scan substantially matches ODS data stored in the controller 190, such as in the library, that corresponds with the endpoint of the polishing process. If it is determined that the endpoint has been reached, the method then moves to operation 646 in which the CMP process is stopped, and in some cases the final scan data (i.e., curve 656) is stored in memory for use by the controller 190 in subsequent endpoint detection steps. If it is determined that the endpoint has not been reached, then the method 630 then moves to operation 644.

If the endpoint has not been achieved, as determined in operation 642, then operation 644 is performed in which the controller 190 then adjusts one or more of the CMP processing parameters (e.g., time, pressure, rotation speed(s) of the platen 202 or carrier head 210, etc.) to drive the current polishing process to the desired endpoint. The amount of adjustment of the one or more of the CMP processing parameters can be based on the deviation in the compared attribute. In one example, due to the faster than expected polishing process removal at the current CMP process after the 28th scan the CMP process needs to be altered to slow the process to achieve the desired endpoint. For example, the carrier head 210 rotational speed may be adjusted to increase or slow down the polishing rate. Method 630 then returns back to operations 636-637, which are then repeated again. Operations 636-644 are typically repeated multiple times during a CMP polishing process before the endpoint is detected during operation 642. Method 630 may repeat at each polishing station 124 within the CMP system 100. In other words, method 630 may be used to determine when the endpoint of the polishing operation occurring at a particular polishing station 124 has been reached.

FIG. 6F illustrates an example of substrate surface signal topography data collected from a model or measured on a substrate 652, according to embodiments described herein. The controller 190 can use the film topography information to determine what the ODS data 655 should include for the substrate 652, so that the determined ODS data 655 could be stored in memory and used as the library data during operation 637. In one example, the topography data can be received from a scan of a reference substrate in the metrology station 117, or by use of the endpoint sensor 224 data collected by scanning the substrate before beginning a CMP process (i.e., before urging the substrate against the polishing pad surface and/or providing a slurry). In one example, the topography data can be generated by modelling techniques based on a prior knowledge of a substrate's or a batch of substrates' topography.

FIG. 6G illustrates an example of multiple alternate scan paths created for a substrate due to variations in the substrate's properties, according to embodiments described herein. Variations a substrate's properties can alter the scan path of the endpoint sensor 224 across the substrate, which will cause a variation in the measured ODS data 655. Differences in a substrate's properties can include substrate size, for example, which can cause the position of the scan paths across the substrate surface to vary slightly from one substrate to the next, which will cause slight variations in the curves 656 in each of the collected ODS data 655 in a series of scans from substrate-to-substrate. The error or variation in the collected ODS data 655 from each successive scan can also cause a drift in the scan path over time during processing. FIG. 6H illustrates plots of substrate scan data collected using a respective scanned paths illustrated in FIG. 6G, according to embodiments described herein. As illustrated in FIG. 6H, the curves 656 for each of the different scan paths “i”, which in FIG. 6G vary from “i+5” to “i−6”. If it is determined that the scan paths deviate from an expected scan path (i.e., i^{th} scan path), the position of the carrier head 210 or the rotational speed of the carrier head 210, for example, can be modified on next few scans to adjust the scan path position according to pre-stored scan profile generated either by theoretical modelling, or experimentally collected profiles.

Additionally, the controller 190 may analyze the data obtained where the scan path of two or more endpoint sensors 224 cross to evaluate the endpoint of the CMP process. For example, the controller 190 may analyze the data obtained at point 511, where the first scan path 501 and third scan path 503 cross, to analyze the endpoint of the CMP process. This data may be used to plot a trace of the CMP process. Additionally, the controller 190 may analyze the data obtained at point 512, where the second scan path 502 and third scan path 503 cross, and point 513, where the first scan path 501 and second scan path 502 cross, to evaluate the endpoint of the CMP process. The data obtained at each point 511, 512, 513 may be used to plot a separate trace of the endpoint process during the endpoint analysis. In some embodiments, the controller 190 may also compare the data obtained where the scan path of two or more endpoint sensors 224 cross to confirm that the data obtained from each endpoint sensor 224 is consistent.

In one embodiment, a method of processing a substrate in a chemical mechanical polishing (CMP) system, comprising performing a polishing process on a plurality of substrates, wherein each polishing process performed on each substrate comprises: transferring each of the substrates of the plurality of substrates to a surface of a first polishing pad, wherein transferring each of the substrates comprises: retrieving, by use of a carrier head that is oriented in first orientation, the substrate that is positioned in a second orientation on a substrate receiving surface within the CMP system; polishing a surface of each of the substrates on the first polishing pad coupled to a first platen, wherein the first platen comprises one or more sensors that are configured to detect a property of a material disposed on the surface of each of the substrates, one of the one or more sensors is positioned in a third orientation, and a controller that is configured to, at a beginning of the process of polishing the surface of each of the substrate, cause the substrate, the carrier head and the one or more sensors on the platen to be positioned in substantially the same orientations relative to each other; scanning, by the one or more sensors, the surface of each of the substrates during the process of polishing the surface of each of the substrates, wherein scanning the surface of each of the substrates comprises generating scan data that comprises a detected property of the material disposed on the surface of each of the substrates; determining that the generated scan data substantially matches library scan data that is stored in memory of the controller; determining a difference exists between an attribute of a portion of the generated scan data with an attribute of a portion of the library scan data; and adjusting a characteristic of the process of polishing the surface of each of the substrates based on the determined difference between the attribute of the portion of the generated scan data and the attribute of the portion of the library scan data.

In one embodiment, a method of processing a substrate in a chemical mechanical polishing (CMP) system, comprising performing a polishing process on a plurality of substrates, wherein each polishing process performed on each substrate comprises transferring each of the substrates of the plurality of substrates to a surface of a first polishing pad. Wherein transferring each of the substrates comprises retrieving, by use of a carrier head that is oriented in first orientation, a substrate that is positioned in a second orientation on a substrate receiving surface within the CMP system. The method further comprises polishing a surface of each of the substrates on the first polishing pad coupled to a first platen. The first platen comprises one or more first sensors that are configured to detect a property of a material disposed on the surface of each of the substrates. The one of the one or more first sensors is positioned in a third orientation. A controller that is configured to, at a beginning of the process of polishing the surface of each of the substrate, cause the substrate, the carrier head and the one or more first sensors on the first platen to be positioned in substantially the same orientations relative to each other. The method further comprises scanning, by the one or more first sensors, the surface of each of the substrates during the process of polishing the surface of each of the substrates on the first polishing pad, wherein scanning the surface of each of the substrates comprises generating first scan data that comprises a first detected property of the material disposed on the surface of each of the substrates. The method further comprises determining a difference exists between an attribute of a portion of the generated first scan data with an attribute of a portion of a first library scan data stored in the controller during the process of polishing the surface of each of the substrates on the first polishing pad. The method further comprises adjusting a characteristic of the process of polishing the surface of each of the substrates on the first polishing pad based on the determined difference between the attribute of the portion of the generated first scan data and the attribute of the portion of the first library scan data.

In one or more embodiments of the method of performing the polishing process, the attribute of the portion of the generated first scan data and the attribute of the portion of the first library data comprises a peak-to-peak variation in the generated first scan data and the first library scan data.

In one or more embodiments of the method of performing the polishing process, the characteristic of the process of polishing the surface of each of the substrates comprises adjusting at least one of an amount of force applied by the carrier head to the substrate, a rotation speed of the carrier head and substrate, and a rotation speed of the first platen.

In one or more embodiments of the method of performing the polishing process, the first library scan data comprises scan data generated from a prior polished substrate polished on the first polishing pad, scan data generated from material property measurements performed on the substrate, or scan data generated by use of a computer generated model.

In one or more embodiments of the method of performing the polishing process, the one or more first sensors comprise eddy current sensors.

In one or more embodiments, the method of performing the polishing process further comprises determining that the generated first scan data substantially matches an endpoint of the first library scan data. The method further comprises stopping the polishing of each substrate on the first polishing pad upon determining that the generated first scan data substantially matches the endpoint of the first library scan data.

In one or more embodiments, the method of performing the polishing process further comprises transferring each substrate from the first polishing pad a second polishing pad coupled to as second platen using the carrier head. The method further comprises moving the carrier head to a scan position above an orientation sensor coupled to the second platen. The method further comprises determining an orientation of the substrate relative to the carrier head using the orientation sensor.

In one or more embodiments, the method of performing the polishing process further comprises polishing each substrate on the second polishing pad. The method further comprises scanning, by one or more second sensors coupled to the second platen, the surface of each of the substrates during the process of polishing the surface of each of the substrates on the second polishing pad, wherein scanning the surface of each of the substrates comprises generating second scan data that comprises a second detected property of the material disposed on the surface of each of the substrates. The method further comprises determining a difference exists between an attribute of a portion of the generated second scan data with an attribute of a portion of a second library scan data stored in the controller during the process of polishing the surface of each of the substrates on the second polishing pad. The method further comprises adjusting a characteristic of the process of polishing the surface of each of the substrates on the second polishing pad based on the determined difference between the attribute of the portion of the first generated scan data and the attribute of the portion of the second library scan data.

In one embodiment, a method of processing a substrate in a chemical mechanical polishing (CMP) system comprises transferring a substrate from a first polishing pad to a second polishing pad using a first carrier head. The method further comprises determining, after transferring the substrate to the second polishing pad, an orientation of the substrate relative to the first carrier head. The method further comprises initiating a polishing process of a surface of the substrate on the second polishing pad. The method further comprises scanning, during the polishing process, a first portion of the surface of the substrate a first time using an endpoint sensor coupled to the second polishing pad to generate first orientation dependent scan data of a property of the first portion of the surface. The method further comprises comparing the first orientation dependent scan data to a first library of orientation dependent scan data. The method further comprises scanning, during the polishing process, the first portion of the surface of the substrate a second time using the endpoint sensor to generate second orientation dependent scan data of the property the first portion of the surface. The method further comprises comparing the second orientation dependent scan data to the first library and determining that the endpoint of the polishing process has been reached. The method further comprises stopping the polishing process upon determining that the endpoint has been reached.

In one or more embodiments of the method, comparing the first orientation dependent scan data to the first library comprises determining that a difference exists between an attribute of a portion of the first orientation dependent scan data and an attribute of a portion of the first library.

In one or more embodiments of the method, the attribute of the portion of the scan data and the attribute of the portion of the first library comprises a peak-to-peak variation in the first orientation dependent scan data and the first library.

In one or more embodiments of the method, the method further comprises adjusting a polishing characteristic of the polishing process based on the determined difference between the attribute of the portion of the first orientation dependent scan data and the attribute of the portion of the first library prior to scanning the first portion of the surface of the substrate the second time using the endpoint sensor.

In one or more embodiments of the method, adjusting the polishing characteristic of the polishing process comprises adjusting at least one of an amount of force applied by the first carrier head to the substrate, a rotation speed of the first carrier head, and a rotation speed of the second polishing pad.

In one or more embodiments of the method, the method further comprises placing the first carrier head and first substrate in a starting position relative to the second polishing pad prior to initiating the polishing process.

In one or more embodiments of the method, the method further comprises scanning, during the polishing process prior to scanning the substrate the second time, a portion of the surface of the substrate using the endpoint sensor to generate third orientation dependent scan data of the property the portion of the surface. The method further comprises determining that the portion of the surface of the substrate scanned by the endpoint sensor during the third scan of the substrate is not the first portion of the substrate. The method further comprises adjusting a position of the first carrier head and/or a rotation speed of the first carrier head such that the endpoint sensor will pass underneath the first portion of the surface during a subsequent scan.

In one embodiment, a method of processing a substrate in a chemical mechanical polishing (CMP) system comprises determining an orientation of a substrate relative to a first carrier head. The method further comprises initiating a first polishing process of a surface of the substrate engaged with a first polishing pad, the first polishing process comprising rotating the first polishing pad and rotating the substrate relative to the first polishing pad using the first carrier head. The method further comprises scanning, during the first polishing process, a first portion of the surface of the substrate a first time using a first endpoint sensor coupled to the first polishing pad to generate first orientation dependent scan data of a property of the first portion of the surface. The method further comprises comparing the first orientation dependent scan data to a first library of orientation dependent scan data. The method further comprises scanning, during the first polishing process, the first portion of the surface of the substrate a second time using the first endpoint sensor to generate second orientation dependent scan data of the property of the first portion of the surface. The method further comprises comparing the second orientation dependent scan data to the first library and determining that an endpoint of the first polishing process has been reached. The method further comprises stopping the first polishing process upon determining that the endpoint of the first polishing process has been reached.

In one or more embodiments, the method further comprises placing the first carrier head and first substrate in a starting position relative to the first endpoint sensor prior to initiating the first polishing process.

In one or more embodiments, the method further comprises scanning, during the first polishing process prior to scanning the substrate the second time, a portion of the surface of the substrate using the first endpoint sensor to generate third orientation dependent scan data of the property of the portion of the surface of the substrate. The method further comprises determining that the portion of the surface of the substrate scanned by the first endpoint sensor during the scan of the substrate is not the first portion of the substrate. The method further comprises adjusting a position of the first carrier head and/or a rotation speed of the first carrier head such that the first endpoint sensor will pass underneath the first portion of the surface during a subsequent scan.

In one or more embodiments, the method further comprises transferring the substrate from the first polishing pad to a second polishing pad. The method further comprises determining, after transferring the substrate to the second polishing pad, an orientation of the substrate relative to the first carrier head. The method further comprises initiating a second polishing process of the surface of the substrate engaged with the second polishing pad, the second polishing process comprising rotating the second polishing pad and rotating the substrate relative to the second polishing pad using the first carrier head. The method further comprises scanning, during the second polishing process, the first portion of the surface of the substrate a first time using a second endpoint sensor coupled to the second polishing pad to generate third orientation dependent scan data of the property of the first portion of the surface. The method further comprises comparing the third orientation dependent scan data to a second library of orientation dependent scan data. The method further comprises scanning, during the second polishing process, the first portion of the surface of the substrate a second time using the second endpoint sensor to generate fourth orientation dependent scan data of the first portion of the surface. The method further comprises comparing the fourth orientation dependent scan data to the second library and determining that the endpoint of the second polishing process has been reached. The method further comprises stopping the second polishing process upon determining that the endpoint of the second polishing process has been reached.

In one or more embodiments of the method, determining the orientation of the substrate relative to the first carrier head includes aligning the substrate in a pre-aligner station.

In one embodiment, a non-transitory computer-readable medium comprising instructions stored thereon that when executed by one or more processors cause a controller to perform a method of processing a substrate in a chemical mechanical polishing (CMP) system, the method comprising determining an orientation of a substrate relative to a first carrier head. The method further comprises initiating a first polishing process of a surface of the substrate engaged with a first polishing pad, the first polishing process comprising rotating the first polishing pad and rotating the substrate relative to the first polishing pad using the first carrier head. The method further comprises scanning, during the first polishing process, a first portion of the surface of the substrate a first time using a first endpoint sensor coupled to the first polishing pad to generate first orientation dependent scan data of a property of the first portion of the surface. The method further comprises comparing the first orientation dependent scan data to a first library of orientation dependent scan data. The method further comprises scanning, during the first polishing process, the first portion of the surface of the substrate a second time using the first endpoint sensor to generate second orientation dependent scan data of the property of the first portion of the surface. The method further comprises comparing the second orientation dependent scan data to the first library and determining that an endpoint of the first polishing process has been reached. The method further comprises stopping the first polishing process upon determining that the endpoint of the first polishing process has been reached.

In one or more embodiments of the medium, the method further comprises placing the first carrier head and first substrate in a starting position relative to the first endpoint sensor prior to initiating the first polishing process.

In one or more embodiments of the medium, the method further comprises scanning, during the first polishing process prior to scanning the substrate the second time, a portion of the surface of the substrate using the first endpoint sensor to generate third orientation dependent scan data of the property of the portion of the surface of the substrate. The method further comprises determining that the portion of the surface of the substrate scanned by the first endpoint sensor during the scan of the substrate is not the first portion of the substrate. The method further comprises adjusting a position of the first carrier head and/or a rotation speed of the first carrier head such that the first endpoint sensor will pass underneath the first portion of the surface during a subsequent scan.

In one or more embodiments of the medium, the method further comprises transferring the substrate from the first polishing pad to a second polishing pad. The method further comprises determining, after transferring the substrate to the second polishing pad, an orientation of the substrate relative to the first carrier head. The method further comprises initiating a second polishing process of the surface of the substrate engaged with the second polishing pad, the second polishing process comprising rotating the second polishing pad and rotating the substrate relative to the second polishing pad using the first carrier head. The method further comprises scanning, during the second polishing process, the first portion of the surface of the substrate a first time using a second endpoint sensor coupled to the second polishing pad to generate third orientation dependent scan data of the property of the first portion of the surface. The method further comprises comparing the third orientation dependent scan data to a second library of orientation dependent scan data. The method further comprises scanning, during the second polishing process, the first portion of the surface of the substrate a second time using the second endpoint sensor to generate fourth orientation dependent scan data of the first portion of the surface. The method further comprises comparing the fourth orientation dependent scan data to the second library and determining that the endpoint of the second polishing process has been reached. The method further comprises stopping the second polishing process upon determining that the endpoint of the second polishing process has been reached.

In one or more embodiments of the medium, determining the orientation of the substrate relative to the first carrier head includes aligning the substrate in a pre-aligner station.

While the foregoing is directed to embodiments of the present disclosure, other and further embodiments of the disclosure may be devised without departing from the basic scope thereof, and the scope thereof is determined by the claims that follow.

What is claimed is:

1. A method of processing a substrate in a chemical mechanical polishing (CMP) system, comprising performing a polishing process on a plurality of substrates, wherein each polishing process performed on each substrate comprises:
transferring each of the substrates of the plurality of substrates to a surface of a first polishing pad, wherein transferring each of the substrates comprises:
retrieving, by use of a carrier head that is oriented in first orientation, a substrate that is positioned in a second orientation on a substrate receiving surface within the CMP system;
polishing a surface of each of the substrates on the first polishing pad coupled to a first platen, wherein:
the first platen comprises one or more first sensors that are configured to detect a property of a material disposed on the surface of each of the substrates,
one of the one or more first sensors is positioned in a third orientation, and
a controller that is configured to, at a beginning of the process of polishing the surface of each of the substrate, cause the substrate, the carrier head and the one or more first sensors on the first platen to be positioned in substantially the same orientations relative to each other;
scanning, by the one or more first sensors, the surface of each of the substrates during the process of polishing the surface of each of the substrates on the first polishing pad, wherein scanning the surface of each of the substrates comprises generating first scan data that comprises a first detected property of the material disposed on the surface of each of the substrates;
determining a difference exists between an attribute of a portion of the generated first scan data with an attribute of a portion of a first library scan data stored in the controller during the process of polishing the surface of each of the substrates on the first polishing pad; and
adjusting a characteristic of the process of polishing the surface of each of the substrates on the first polishing pad based on the determined difference between the attribute of the portion of the generated first scan data and the attribute of the portion of the first library scan data.

2. The method of claim 1, wherein the attribute of the portion of the generated first scan data and the attribute of the portion of the first library data comprises a peak-to-peak variation in the generated first scan data and the first library scan data.

3. The method of claim 1, wherein the characteristic of the process of polishing the surface of each of the substrates comprises adjusting at least one of an amount of force applied by the carrier head to the substrate, a rotation speed of the carrier head and substrate, and a rotation speed of the first platen.

4. The method of claim 1, wherein the first library scan data comprises scan data generated from a prior polished substrate polished on the first polishing pad, scan data generated from material property measurements performed on the substrate, or scan data generated by use of a computer generated model.

5. The method of claim 1, wherein the one or more first sensors comprise eddy current sensors.

6. The method of claim 1, further comprising:
determining that the generated first scan data substantially matches an endpoint of the first library scan data; and
stopping the polishing of each substrate on the first polishing pad upon determining that the generated first scan data substantially matches the endpoint of the first library scan data.

7. The method of claim 6, further comprising:
transferring each substrate from the first polishing pad a second polishing pad coupled to as second platen using the carrier head;
moving the carrier head to a scan position above an orientation sensor coupled to the second platen; and
determining an orientation of the substrate relative to the carrier head using the orientation sensor.

8. The method of claim 7, further comprising:
polishing each substrate on the second polishing pad;
scanning, by one or more second sensors coupled to the second platen, the surface of each of the substrates during the process of polishing the surface of each of the substrates on the second polishing pad, wherein scanning the surface of each of the substrates comprises generating second scan data that comprises a second detected property of the material disposed on the surface of each of the substrates;
determining a difference exists between an attribute of a portion of the generated second scan data with an attribute of a portion of a second library scan data stored in the controller during the process of polishing the surface of each of the substrates on the second polishing pad; and
adjusting a characteristic of the process of polishing the surface of each of the substrates on the second polishing pad based on the determined difference between the attribute of the portion of the first generated scan data and the attribute of the portion of the second library scan data.

9. A method of processing a substrate in a chemical mechanical polishing (CMP) system, comprising:
transferring a substrate from a first polishing pad to a second polishing pad using a first carrier head;
determining, after transferring the substrate to the second polishing pad, an orientation of the substrate relative to the first carrier head;
initiating a polishing process of a surface of the substrate on the second polishing pad;
scanning, during the polishing process, a first portion of the surface of the substrate a first time using an endpoint sensor coupled to the second polishing pad to generate first orientation dependent scan data of a property of the first portion of the surface;
comparing the first orientation dependent scan data to a first library of orientation dependent scan data;
scanning, during the polishing process, the first portion of the surface of the substrate a second time using the endpoint sensor to generate second orientation dependent scan data of the property the first portion of the surface;
comparing the second orientation dependent scan data to the first library and determining that the endpoint of the polishing process has been reached; and
stopping the polishing process upon determining that the endpoint has been reached.

10. The method of claim 9, wherein comparing the first orientation dependent scan data to the first library comprises determining that a difference exists between an attribute of a portion of the first orientation dependent scan data and an attribute of a portion of the first library.

11. The method of claim 10, wherein the attribute of the portion of the scan data and the attribute of the portion of the first library comprises a peak-to-peak variation in the first orientation dependent scan data and the first library.

12. The method of claim 10, further comprising:
adjusting a polishing characteristic of the polishing process based on the determined difference between the attribute of the portion of the first orientation dependent scan data and the attribute of the portion of the first library prior to scanning the first portion of the surface of the substrate the second time using the endpoint sensor.

13. The method of claim 12, wherein adjusting the polishing characteristic of the polishing process comprises adjusting at least one of an amount of force applied by the first carrier head to the substrate, a rotation speed of the first carrier head, and a rotation speed of the second polishing pad.

14. The method of claim 9, further comprising:
placing the first carrier head and first substrate in a starting position relative to the second polishing pad prior to initiating the polishing process.

15. The method of claim 9, further comprising:
scanning, during the polishing process prior to scanning the substrate the second time, a portion of the surface of the substrate using the endpoint sensor to generate third orientation dependent scan data of the property the portion of the surface;
determining that the portion of the surface of the substrate scanned by the endpoint sensor during the third scan of the substrate is not the first portion of the substrate; and
adjusting a position of the first carrier head and/or a rotation speed of the first carrier head such that the endpoint sensor will pass underneath the first portion of the surface during a subsequent scan.

16. A non-transitory computer-readable medium comprising instructions stored thereon that when executed by one or more processors cause a controller to perform a method of processing a substrate in a chemical mechanical polishing (CMP) system, the method comprising:
determining an orientation of a substrate relative to a first carrier head;
initiating a first polishing process of a surface of the substrate engaged with a first polishing pad, the first polishing process comprising rotating the first polishing pad and rotating the substrate relative to the first polishing pad using the first carrier head;
scanning, during the first polishing process, a first portion of the surface of the substrate a first time using a first endpoint sensor coupled to the first polishing pad to generate first orientation dependent scan data of a property of the first portion of the surface;
comparing the first orientation dependent scan data to a first library of orientation dependent scan data;
scanning, during the first polishing process, the first portion of the surface of the substrate a second time using the first endpoint sensor to generate second orientation dependent scan data of the property of the first portion of the surface;
comparing the second orientation dependent scan data to the first library and determining that an endpoint of the first polishing process has been reached; and
stopping the first polishing process upon determining that the endpoint of the first polishing process has been reached.

17. The medium of claim 16, the method further comprising:
placing the first carrier head and first substrate in a starting position relative to the first endpoint sensor prior to initiating the first polishing process.

18. The medium of claim 16, the method further comprising:
scanning, during the first polishing process prior to scanning the substrate the second time, a portion of the surface of the substrate using the first endpoint sensor to generate third orientation dependent scan data of the property of the portion of the surface of the substrate;
determining that the portion of the surface of the substrate scanned by the first endpoint sensor during the scan of the substrate is not the first portion of the substrate; and
adjusting a position of the first carrier head and/or a rotation speed of the first carrier head such that the first endpoint sensor will pass underneath the first portion of the surface during a subsequent scan.

19. The medium of claim 16, the method further comprising:
transferring the substrate from the first polishing pad to a second polishing pad;
determining, after transferring the substrate to the second polishing pad, an orientation of the substrate relative to the first carrier head;
initiating a second polishing process of the surface of the substrate engaged with the second polishing pad, the second polishing process comprising rotating the second polishing pad and rotating the substrate relative to the second polishing pad using the first carrier head;
scanning, during the second polishing process, the first portion of the surface of the substrate a first time using a second endpoint sensor coupled to the second polishing pad to generate third orientation dependent scan data of the property of the first portion of the surface;
comparing the third orientation dependent scan data to a second library of orientation dependent scan data;
scanning, during the second polishing process, the first portion of the surface of the substrate a second time using the second endpoint sensor to generate fourth orientation dependent scan data of the first portion of the surface;
comparing the fourth orientation dependent scan data to the second library and determining that the endpoint of the second polishing process has been reached; and
stopping the second polishing process upon determining that the endpoint of the second polishing process has been reached.

20. The medium of claim 16, wherein determining the orientation of the substrate relative to the first carrier head includes aligning the substrate in a pre-aligner station.
